(19) United States
(12) Patent Application Publication
(10) Pub. No.: US 2020/0161162 A1
(43) Pub. Date: May 21, 2020

(54) SYSTEMS AND METHODS FOR WORKPIECE PROCESSING

(71) Applicants: Mattson Technology, Inc., Fremont, CA (US); Beijing E-Town Semiconductor Technology, Co., LTD, Beijing (CN)

(72) Inventors: Michael X. Yang, Palo Alto, CA (US); Ryan M. Pakulski, Brentwood, CA (US); Pete Lembesis, Boulder Creek, CA (US)

(21) Appl. No.: 16/667,986

(22) Filed: Oct. 30, 2019

Related U.S. Application Data
(60) Provisional application No. 62/769,152, filed on Nov. 19, 2018.

(51) Int. Cl. H01L 21/687; H01L 21/67; H01L 21/677

(52) U.S. Cl. CPC H01L 21/68707; H01L 21/67754; H01L 21/67207; H01L 21/67167

(57) ABSTRACT

Systems and methods for processing workpieces, such as semiconductor workpieces are provided. In one example implementation, an apparatus includes a first processing chamber comprising a first processing station and a second processing station. The first processing station and the second processing station are separated by a first distance. The apparatus includes one or more second processing chambers. The one or more second processing chambers collectively comprising a third processing station and a fourth processing station. The third processing station and the fourth processing station are separated by a second distance. The second distance is different from the first distance. A workpiece handling robot is configured to pick up the at least one first workpiece and the at least one second workpiece from the first and second processing stations and to drop off the at least one first workpiece and the second workpiece at the third and fourth processing stations.

### PRIORITY CLAIM

The present application claims the benefit of priority of U.S. Provisional Application Ser. No. 62/769,152, titled “Systems and Methods for Workpiece Processing,” filed on Nov. 19, 2018, which is incorporated herein by reference.

### FIELD

The present disclosure relates generally to processing workpieces and more particularly to systems for processing workpieces, such as semiconductor workpieces.

### BACKGROUND

Processing systems which expose workpieces such as, semiconductor wafers or other suitable substrates, to an overall manufacturing scheme of fabricating semiconductor devices or other devices can perform a plurality of manufacturing process steps, such as patterning, film deposition (e.g., chemical vapor deposition, physical vapor deposition, plasma enhanced vapor deposition), film removal (e.g., dry etch, dry strip, wet etch), ion implantation, thermal treatment, surface cleaning, surface treatment (e.g. oxidation, nitridation, surface wetting angle tuning), etc. Many of these manufacturing steps occur in a vacuum or near vacuum pressure. Different vacuum processing chambers can have different designs and configurations. To carry out these treatment steps, a system may include one or more workpiece handling robots to move workpieces a number of different times, for example, into the system, between various processing chambers, and out of the system.

### SUMMARY

Aspects and advantages of embodiments of the present disclosure will be set forth in part in the following description, or may be learned from the description, or may be learned through practice of the embodiments.

One example aspect of the present disclosure is directed to a workpiece processing apparatus for processing semiconductor workpieces. The apparatus includes a first processing chamber having a first processing station and a second processing station. The first processing chamber is operable at a pressure of less than about 10 torr. The first processing station and the second processing station are separated by a first distance. The apparatus includes one or more second processing chambers. The one or more second processing chambers collectively comprising a third processing station and a fourth processing station. The one or more second processing chambers are operable at a pressure of less than about 10 torr. The third processing station and the fourth processing station are separated by a second distance. The second distance is different from the first distance. The apparatus includes a transfer chamber in process flow communication with the first processing chamber and the one or more second processing chambers. The transfer chamber is operable at a pressure of less than about 10 torr. The apparatus includes a workpiece handling robot disposed in the transfer chamber, the workpiece handing robot configured to rotate about an axis. The workpiece handling robot includes a first arm and a second arm. The first arm includes at least one workpiece handling component operable to support a first workpiece. The second arm includes at least one workpiece handling component operable to support a second workpiece. The workpiece handling robot is configured to pick up the at least one first workpiece and the at least one second workpiece from the first and second processing stations and to drop off the at least one first workpiece and the second workpiece at the third and fourth processing stations.

Other example aspects of the present disclosure are directed to systems, methods, and apparatus for processing semiconductor workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example processing platform according to example embodiments of the present disclosure;

FIG. 2 depicts an example workpiece column according to example embodiments of the present disclosure;

FIG. 3 depicts an example workpiece handling robot according to example embodiments of the present disclosure;

FIG. 4 depicts an example workpiece handling robot according to example embodiments of the present disclosure;

FIGS. 5A, 5B, 5C, and 5D depict an example transfer of workpieces in an example processing platform according to example embodiments of the present disclosure;

FIGS. 6A, 6B, 6C, 6D, 6E, and 6F depict an example transfer of workpieces in an example processing platform according to example embodiments of the present disclosure; and

FIG. 7 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems and methods for processing workpieces, such as semiconductor workpieces, such as semiconductor wafers. The workpiece materials can include, for instance, silicon, silicon germanium, glass, plastic, or other suitable material. The systems and methods can be used to implement a variety of workpiece manufacturing processes, including, but not limited to thermal processes, anneal processes, surface cleaning processes, surface treatment processes, dry strip processes, dry etch processes, deposition processes, ion implantation processes, and other processes.

Semiconductor manufacturing can involve many processing steps that occur in a vacuum or near vacuum pressure, including film deposition (e.g., chemical vapor deposition, physical vapor deposition, plasma enhanced vapor deposition), film removal (e.g., ion and radical based dry etch, ion and radical based dry photoresist strip, chemical based dry etch), ion implantation, vacuum thermal treatment, etc. Different vacuum processing chambers can have different designs and configurations.

Some processing chambers can be configured to handle a single workpiece at a time (e.g., single workpiece chambers). Single workpiece chambers can have advantages in precise control of individual workpiece processing, for increased workpiece-to-workpiece repeatability and process control consistency.

Some processing chamber designs can be configured to process two workpieces at a time (e.g., dual workpiece chambers). Dual workpiece chambers can adopt a single set of hardware (e.g., common chamber body, common chamber lid, shared gas delivery system, shared gas exhaust system, common heater block, etc.). Compared with single workpiece chambers, dual workpiece chambers can provide for smaller footprint (per workpiece) and higher throughput. Depending on the different design parameters for different process conditions, a spacing between workpieces in different dual workpiece chambers can be different.

Semiconductor workpiece processing systems can include many processing chambers integrated in process flow communication with a transfer chamber. The processing chambers and transfer chamber can be operated at a vacuum pressure or near vacuum pressure. One or more workpieces can be transferred from a load lock chamber into the transfer chamber (e.g., using a workpiece handling robot) and subsequently transferred to one or more of the processing chambers without vacuum break.

As an example, in some semiconductor workpiece manufacturing processes, certain sequential process steps need to be configured in one processing platform with vacuum transfer (or near vacuum transfer) between processing chambers to reduce and/or eliminate surface oxidation and workpiece outgassing. These process integrations can include, for instance: (1) ion implantation on a workpiece masked by a patterned photoresist layer followed by photoresist strip; (2) ion or radical or chemical dry etch on a workpiece masked by a patterned photoresist layer followed by photoresist strip; (3) multiple film deposition steps in sequence (e.g., sequential poly-silicon deposition and metal deposition without vacuum break to form an oxygen-free interface); (4) multiple film etch steps in sequence (e.g., a dielectric film etch process followed by a metal film etch process); (5) film deposition followed by film etch (e.g., a dielectric deposition process followed by a dielectric etch process in a spacer formation scheme); (6) surface treatment followed by film deposition (e.g., surface cleaning followed by an epitaxial film growth); (7) film deposition followed by surface treatment; (8) surface treatment followed by film etch; (9) surface treatment followed by surface treatment; (10) film deposition followed by rapid thermal annealing; etc.

Workpiece handling robots can be used to transfer workpieces among different processing chambers and other components (e.g., load lock chamber) in a workpiece processing system. For instance, a workpiece handling robot can be rotated to be in front of a single workpiece chamber. A workpiece can be transferred into the single workpiece chamber with an extension of an arm on the workpiece handling robot. Multiple single workpiece chambers of the same or different kinds can be integrated on a single transfer chamber.

Workpiece transfer to dual workpiece chambers can consider the positioning of two workpieces at two processing stations within the same chamber. A workpiece handling robot configured to transfer workpieces to a dual workpiece chamber can include two arms with fixed spacing between the arms to align with the space between two processing stations within the dual workpiece chamber. To position two workpieces in the dual workpiece chamber at the same time, the workpiece handling robot can be rotated in front of the dual workpiece chamber and the two arms of the workpiece handling robot can be extended to place the workpieces at respective processing stations in the dual workpiece chamber.

In some cases, it may be desirable to integrate dual workpiece chambers with different spacing between workpieces on a single transfer chamber in a processing platform. In addition, it may be desirable to include one or more single workpiece chambers on the single transfer chamber in the processing platform.

According to example aspects of the present disclosure, a workpiece handling robot can be configured to transfer workpieces among a plurality of different processing chamber designs in process flow communication with a single transfer chamber. In some embodiments, the different processing chamber designs can include, for instance, multiple dual workpiece chambers with different spacing between processing stations. In some embodiments, the different processing chamber designs can include, for instance, a dual workpiece chamber and one or more single workpiece chambers. In some embodiments, the different processing chamber designs can include multiple dual workpiece chambers (e.g., with different spacing between processing stations) and one or more single workpiece chambers.

In some example embodiments, a workpiece handling robot can have two arms. Each arm can have a workpiece handling component (e.g., workpiece blade, end effector, etc.) configured to pick up, support, and/or drop off one or more workpieces. The workpiece handling robot can have a first degree of freedom about a rotational axis that allows the workpiece handling robot to rotate about an axis in a transfer chamber. The workpiece handling robot can have a second degree of freedom in extension of the two arms. According to particular aspects of the present disclosure, the workpiece handling robot can have a third degree of freedom that allows for adjustment of spacing (e.g., lateral spacing) between the two arms. The spacing between the two arms can be adjusted to align with different spacing between workpiece processing stations in different dual workpiece chambers integrated onto the transfer chamber.

In some example embodiments, a workpiece handling robot can have two or more arms. Each arm can have a workpiece handling component (e.g., workpiece blade, end effector, etc.) configured to pick up, support, and/or drop off one or more workpieces. The workpiece handling robot can have a first degree of freedom about a rotational axis that allows the workpiece handling robot to rotate about an axis in a transfer chamber. The workpiece handling robot can have a second degree of freedom in extension of the two or more arms. According to particular aspects of the present disclosure, the robot arms are independently extendable relative to one another such that two or more workpieces can be delivered independently to different workpiece processing stations in a dual workpiece chamber. This can accommodate transfer of workpieces to multiple dual workpiece chambers with different spacing between workpiece processing stations. In addition, the independent extension of arms can provide for the delivery of workpieces to single workpiece chambers as well. This can allow for the integration of single workpiece chambers and dual workpiece chambers on the same transfer chamber.

In this way, example aspects of the present disclosure can have a number of technical effects and benefits. For instance, multiple different workpiece processing chambers can be integrated onto a single transfer chamber in a processing platform. Workpieces can be transferred among the different workpiece processing chambers using a single workpiece handling robot without vacuum break. In this way, multiple process integrations can be implemented on the workpiece processing platform. These process integrations can include, for instance: (1) ion implantation on a workpiece masked by a patterned photoresist layer followed by photoresist strip; (2) ion or radical or chemical dry etch on a workpiece masked by a patterned photoresist layer followed by photoresist strip; (3) multiple film deposition steps in sequence (e.g., sequential poly-silicon deposition and metal deposition without vacuum break to form an oxygen-free interface); (4) multiple film etch steps in sequence (e.g., a dielectric film etch process followed by a metal film etch process); (5) film deposition followed by film etch (e.g., a dielectric deposition process followed by a dielectric etch process in a spacer formation scheme); (6) surface treatment followed by film deposition (e.g., surface cleaning followed by an epitaxial film growth); (7) film deposition followed by surface treatment; (8) surface treatment followed by film etch; (9) surface treatment followed by surface treatment; (10) film deposition followed by rapid thermal annealing; etc.

Variations and modifications can be made to these example embodiments of the present disclosure. As used in the specification, the singular forms “a,” “and,” and “the” include plural referents unless the context clearly dictates otherwise. The use of “first,” “second,” “third,” and “fourth” are used as identifiers and are directed to an order of processing. Example aspects may be discussed with reference to a “substrate,” “wafer,” or “workpiece” for purposes of illustration and discussion. Those of ordinary skill in the art, using the disclosures provided herein, will understand that example aspects of the present disclosure can be used with any suitable workpiece. The use of the term “about” in conjunction with a numerical value refers to within 20% of the stated numerical value. As used herein, “near vacuum” refers to less than about 10 Torr.

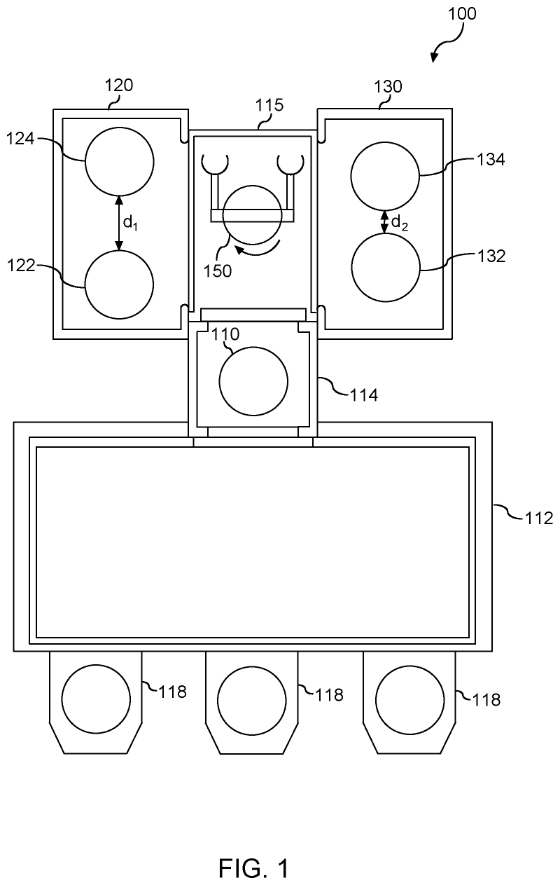

With reference now to the FIGS., example embodiments of the present disclosure will now be discussed in detail. FIG. 1 depicts a processing platform 100 according to example embodiments of the present disclosure. The processing platform 100 can include a front end portion 112, a load lock chamber 114, a transfer chamber 115 and a plurality of processing chambers, including a first processing chamber 120 and a second processing chamber 130.

The front end portion 112 can be configured to be maintained, for instance, at atmospheric pressure and can be configured to engage workpiece input devices 118. The workpiece input devices 118 can include, for instance, cassettes, front opening unified pods, or other devices for supporting a plurality of workpieces. Workpiece input devices 118 can be used to provide pre-process workpieces to the processing platform 100 or to receive post-process workpieces from the processing platform 100.

The front end portion 112 can include one or more workpiece handling robots (not illustrated) for transferring workpieces from workpiece input devices 118 to, for instance, the load lock chamber 114, such as to and from a workpiece support column 110 located in the load lock chamber 114. In one example, the workpiece handling robot in the front end portion 112 can transfer preprocess workpieces to the load lock chamber 114 and can transfer post-process workpieces from the load lock chamber 114 to one or more of the workpiece input devices 118. Any suitable robot for transferring workpieces can be used in the front end portion 112 without deviating from the scope of the present disclosure. Workpieces can be transferred to and or from the load lock chamber 114 through a suitable slit, opening, or aperture.

The load lock chamber 114 can include a transfer position having a workpiece support column 110 configured to support a plurality of workpieces in a stacked arrangement. The workpiece support column 110 can include, for instance, a plurality of shelves. Each shelf can be configured to support one or more workpieces. In one example implementation, the workpiece support column 110 can include one or more shelves for supporting preprocess workpieces and one or more shelves for supporting post-process workpieces.

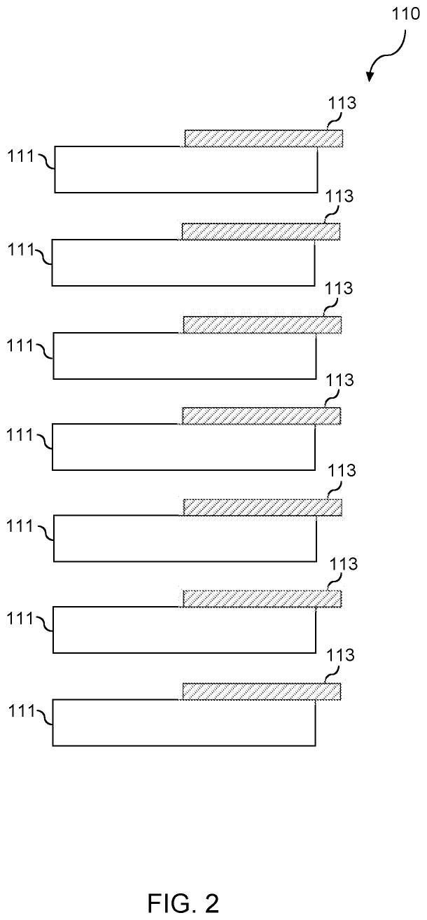

FIG. 2 depicts a side view of an example workpiece support column 110 according to example embodiments of the present disclosure. As shown, the workpiece support column can include a plurality of shelves 111. Each shelf 111 can be configured to support a workpiece 113 so that a plurality of workpieces 113 can be arranged on the workpiece support column 110 in a vertical/stacked arrangement.

Referring to FIG. 1, the load lock chamber 114 can be used to adjust the pressure surrounding the workpieces from the pressure associated with the front end portion 112 to a process pressure, such as a vacuum or near vacuum pressure or other process pressure, prior to transfer of the workpieces to processing chambers, such as first processing chamber 120 and/or second processing chamber 130. In some embodiments, appropriate valves can be provided in conjunction with the load lock chamber 114 and other chambers to appropriately adjust the process pressure for processing the workpieces. The load lock chamber 114 can be isolated from the transfer chamber 115, for instance, by a slit door. The load lock chamber 114 can be operable at a pressure from less than about 10 torr to atmospheric pressure.

The first processing chamber 120 and the second processing chamber 130 can be used to perform any of a variety of workpiece processing on the workpieces, such as vacuum anneal processes, surface treatment processes, dry strip processes, dry etch processes, deposition processes, and other processes. For instance, the first processing chamber 120 and/or the second processing chamber 130 can be one or more of an etch process chamber, a dry strip process chamber, a deposition process chamber, a thermal process chamber (e.g., an anneal process chamber), an ion implantation process chamber, or a surface treatment process chamber. In some embodiments, one or more of the first processing chamber 120 and/or the second processing chamber 130 can include plasma-based process sources such as, for example, inductively coupled plasma (ICP) sources, microwave sources, surface wave plasma sources, ECR plasma sources, and capacitively coupled (parallel plate) plasma sources. The first processing chamber 120 and the second processing chamber 130 be operable at a pressure of less than about 10 torr.

As illustrated, each of the first processing chamber 120 and second processing chamber 130 are dual workpiece processing chambers. The first processing chamber 120 and the second processing chamber 130 each include a pair of processing stations in side-by-side arrangement so that a pair of workpieces can be simultaneously exposed to the same process.

More particularly, the first processing chamber 120 can include a first processing station 122 and a second processing station 124 in side-by-side arrangement. The first processing station 122 and the second processing station 124 can be separated by a first distance d₁. The second processing chamber 130 can include a third processing station 132 and a fourth processing station 134 in side-by-side arrangement. The third processing station 132 and the fourth processing station 134 can be separated by a second distance d₂. The second distance d₂ can be different from the first distance d₁. For instance, the second distance d₂ can be smaller than the first distance d₁.

Each processing station can include a workpiece support (e.g., a pedestal) for supporting a workpiece during processing. In some embodiments, each processing station can share a common pedestal with two portions for supporting a workpiece. The first processing chamber 120 and/or the second processing chamber 130 can be selectively sealed off from the transfer chamber 115 for processing.

According to particular aspects of the present disclosure, the transfer chamber 115 can include a workpiece handling robot 150. The workpiece handling robot 150 can be configured to transfer workpieces from the workpiece support column 110 in the load lock chamber 114 to the processing stations in the first processing chamber 120 and/or the second processing chamber 130. The workpiece handling robot 150 can also transfer workpieces between the first processing chamber 120 and the second processing chamber 130. For example, the workpiece handling robot 150 can transfer the workpieces from the workpiece support column 110 in the load lock chamber 114 to the two side-by-side processing stations 122 and 124 in the first processing chamber 120. Similarly, the workpiece handling robot 150 can transfer workpieces from the workpiece support column 110 in the load lock chamber 114 to the two side-by-side processing stations 132 and 134 in the second processing chamber 130.

According to example aspects of the present disclosure, the workpiece handling robot 150 can have a variety of configurations to support the transfer of workpieces among different processing chamber designs, such as between processing chamber 120 and processing chamber 130 having processing stations separated by different distances.

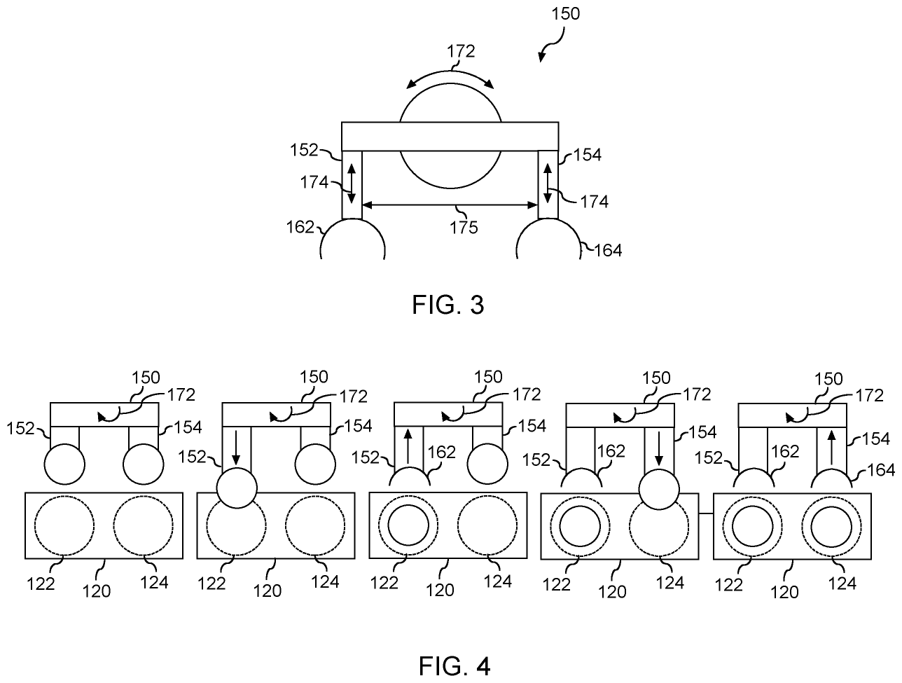

FIG. 3 depicts an example workpiece handling robot 150 configured to transfer workpieces according to example embodiments of the present disclosure. The workpiece handling robot can include a first robot arm 152 and a second robot arm 154. A first workpiece handling component 162 can be associated with the first robot arm 152. The first workpiece handling component 162 can be a workpiece blade, end effector, etc. configured to pick up, hold, and drop off one or more workpieces. A second workpiece handling component 164 can be associated with the second robot arm 154. The second workpiece handling component 164 can be a workpiece blade, end effector, etc. configured to pick up, hold, and drop off one or more workpieces.

The workpiece handling robot 150 is configured to operate in at least three degrees of freedom. For instance, the workpiece handling robot 150 can operate in a first degree of freedom 172 such that the workpiece handling robot 150 can rotate about an axis. In this way, the workpiece handling robot 150 can rotate about an axis in the transfer chamber 115 of platform 100 (FIG. 1) to selectively position the robot arms 152 and 154 in front of the load lock chamber 114, first processing chamber 120 and second processing chamber 130.

Referring to FIG. 3, the workpiece handling robot 150 has a second degree of freedom 174 such that both of the robot arms 152 and 154 are extended and/or retracted in the same direction at the same time (e.g., not independently). In this way, the first robot arm 152 and the second robot arm 154 can be simultaneously extended to pick up and/or drop off workpieces from the processing stations in the first processing station 120 and the second processing station 130.

As shown in FIG. 3, the workpiece handling robot 150 has a third degree of freedom 175 that provides for lateral adjustment of a distance between the first robot arm 152 and the second robot arm 154. In this way, the workpiece handling robot 150 can accommodate the transfer of workpieces among processing stations separated by different distances in the first processing chamber 120 and the second processing chamber 130.

More particularly, referring to FIG. 1, the workpiece handling robot 150 can be rotated to a first position such that first robot arm 152 and second robot arm 154 are facing the first processing chamber 120. The lateral distance between the first robot arm 152 and the second robot arm 154 can be adjusted based on the distance d₁ between the first processing station 122 and the second processing station 124. The first robot arm 152 and the second robot arm 154 can be extended to pick up and/or drop off workpieces simultaneously from the first processing station 122 and the second processing station 124.

The workpiece handling robot 150 can be rotated to a second position such that first robot arm 152 and second robot arm 154 are facing the second processing chamber 130. The lateral distance between the first robot arm 152 and the second robot arm 154 can be adjusted based on the distance d₂ between the third processing station 132 and the fourth processing station 134. The first robot arm 152 and the second robot arm 154 can be extended to pick up and/or drop off workpieces simultaneously from the third processing station 132 and the fourth processing station 134.

FIG. 4 depicts an example workpiece handling robot 150 configured to transfer workpieces according to example embodiments of the present disclosure. The workpiece handling robot 150 of FIG. 4 is configured to transfer workpieces to different processing stations using independent extensions of arms according to example aspects of the present disclosure.

For instance, the workpiece handling robot 150 can include a first robot arm 152 and a second robot arm 154. A first workpiece handling component 162 can be associated with the first robot arm 152. The first workpiece handling component 162 can be a workpiece blade, end effector, etc. configured to pick up, hold, and drop off one or more workpieces. A second workpiece handling component 164 can be associated with the second robot arm 162. The second workpiece handling component 164 can be a workpiece blade, end effector, etc. configured to pick up, hold, and drop off one or more workpieces.

The workpiece handling robot 150 can operate in a rotational degree of freedom 172 such that the workpiece handling robot 150 can rotate about an axis. In this way, the workpiece handling robot 150 can rotate about an axis in the transfer chamber 115 of platform 100 (e.g., FIG. 1) to selectively position the robot arms 152 and 154 in front of the load lock chamber 114, first processing chamber 120 and second processing chamber 130.

The workpiece handling robot 150 can be configured to independently extend and/or retract (e.g., using independent drive mechanisms) the two robot arms to transfer workpieces to, for instance, two processing stations 122 and 124 in a processing chamber 120. For instance, as illustrated in FIG. 4, the workpiece handling robot 150 can be rotated to a position where the first robot arm 152 and the second robot arm 154 face the processing chamber 120. The first robot arm 152 can be independently extended relative to the second robot arm 154 to place a workpiece at a first processing station 122 in the processing chamber 120. Once the workpiece is positioned at the first processing station 122, the first robot arm 152 can be independently retracted relative to the second robot arm 154. The second robot arm 154 can be independently extended relative to the first robot arm 152 to place a workpiece at a second processing station 124 in the processing chamber 120. Once the workpiece is positioned at the second processing station 124, the second robot arm 154 can be independently retracted relative to the first robot arm 152. The robot arms 152 and 154 can be independently extended and retracted in sequential manner as depicted in FIG. 4.

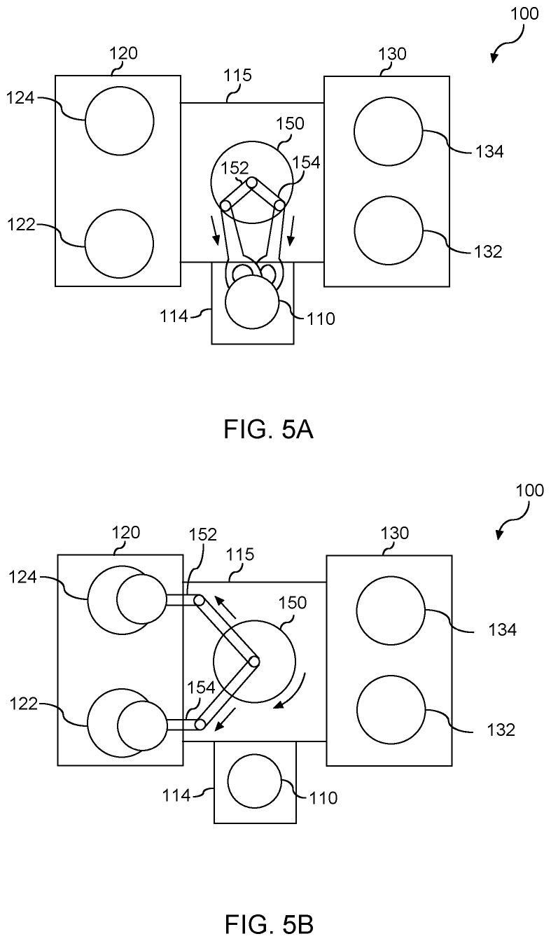

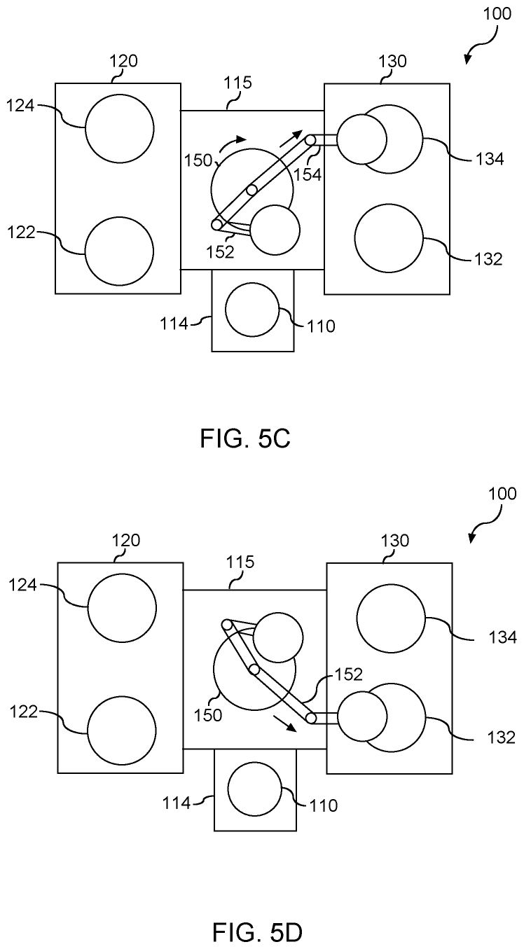

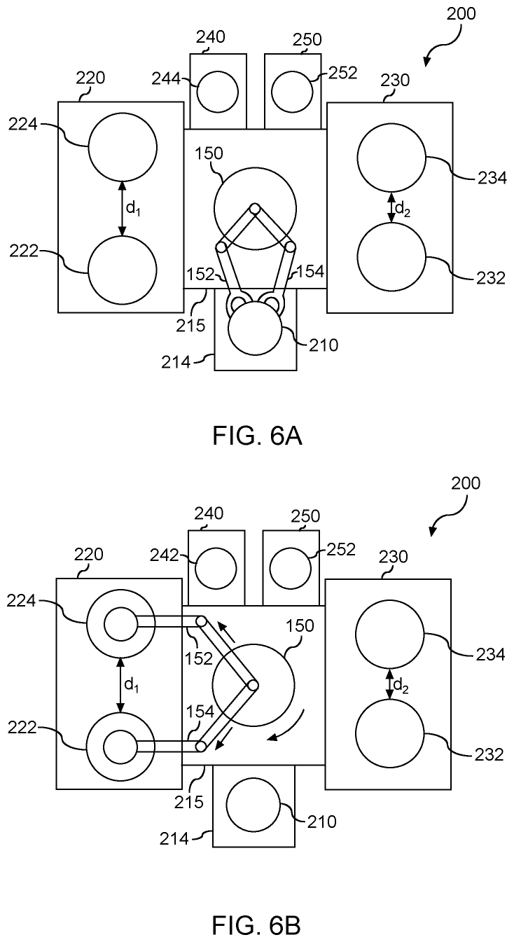

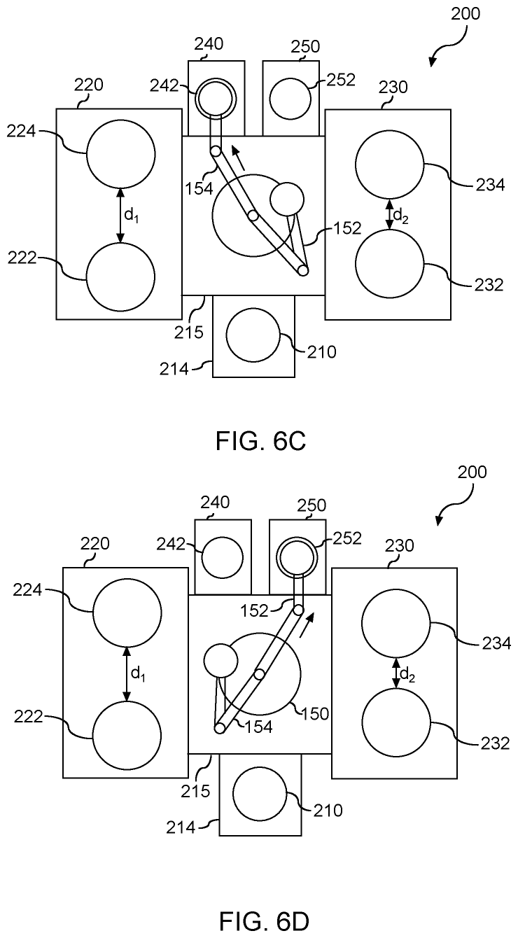

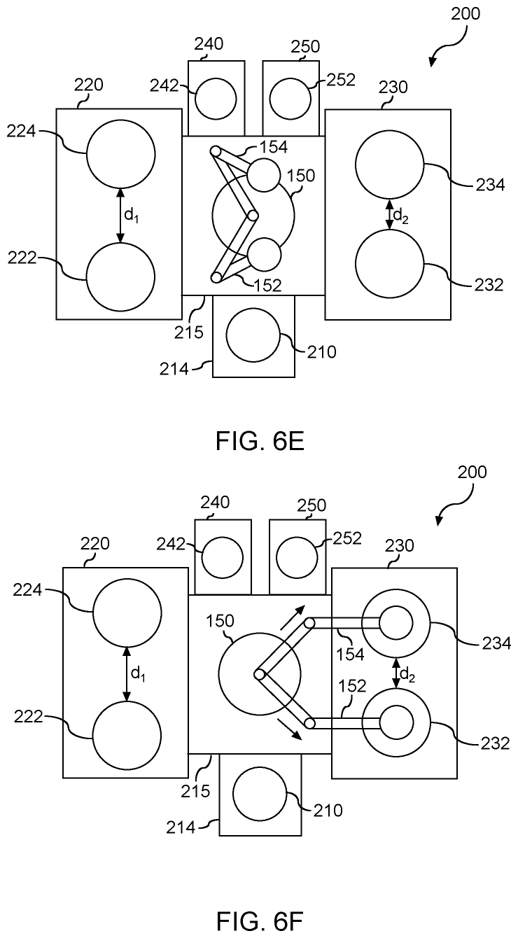

In addition and/or in the alternative, the robot arms 152 and 154 can be independently extended and/or retracted to pick up and/or drop off workpieces at different processing stations at the same time. In this way, the workpiece handling robot 150 of FIG. 4 can accommodate the transfer of workpieces among processing stations separated by different distances in the first processing chamber 120 and the second processing chamber 130. Example transfer of workpieces using the workpiece handling robot 150 of FIG. 4 will be discussed in more detail with references to FIGS. 5A, 5B, 5C, 5D, and 6A, 6B, 6C, 6D, 6E, and 6F below.

Referring to FIGS. 5A to 5D, the operation of an example workpiece handling robot 150 in a processing platform 100 according to example embodiments of the present disclosure will be set forth. The workpiece handling robot 150 can be similar to the workpiece handling robot 150 shown in FIG. 4 and can be configured to provide for the independent extension and/or retraction of each of a plurality of robot arms.

More particularly, for instance, the workpiece handling robot 150 can include a first robot arm 152 and a second robot arm 154. A first workpiece handling component can be associated with the first robot arm 152. The first workpiece handling component can be a workpiece blade, end effector, etc. configured to pick up, hold, and drop off one or more workpieces. A second workpiece handling component can be associated with the second robot arm 154. The second workpiece handling component can be a workpiece blade, end effector, etc. configured to pick up, hold, and drop off one or more workpieces.

As shown in FIG. 5A, both robot arms 152 and 154 of the rotary robot 150 can be independently extended to grab a workpiece from the workpiece support column 110 in the load lock chamber 114. For instance, robot arm 152 can be extended to grab a workpiece from workpiece support column 110. Robot arm 154 can be extended to grab a workpiece from workpiece support column 110. In some embodiments, the robot arms 152 and 154 can be extended to grab workpieces from the workpiece support column 110 at the same time. After grabbing the workpieces from the workpiece support column, the workpiece handling robot 150 can then be operated to retract the robot arms 152 and 154 to a retracted position.

As shown in FIG. 5B, the workpiece handling robot 150 can be rotated so that the robot arms 152 and 154 face a first processing chamber 120. The first processing chamber can be a dual workpiece processing chamber having a first processing station 122 and a second processing station 124 separated by a distance d₁. The robot arms 152 and 154 can be extended independent of one another (e.g., using independent drive mechanisms) to individually place a workpiece on the first processing station 122 and the second processing station 124 respectively. As shown in FIG. 5B, the workpiece handling robot 150 can be configured to extend the robot arms 152 and 154 to place the workpieces on the first processing station 122 and the second procession station 124 at the same time.

The workpieces can be subjected to a first process (e.g., a thermal treatment process, anneal process, etch process, strip process, deposition process, surface treatment process) in the first processing chamber 120. After completion of the first process, the workpiece handling robot 150 can be configured to grab the workpieces from the workpiece processing station 122 and 124 using independent extension of robot arms 152 and 154. After grabbing the workpieces, the workpiece handling robot 150 can then be operated to retract the robot arms 152 and 154 (e.g., using independent drive mechanisms) to a retracted position.

As shown in FIG. 5C, the workpiece handling robot 150 can be rotated so that the robot arms 152 and 154 face a second processing chamber 130. The second processing chamber can be a dual workpiece processing chamber having a third processing station 132 and a fourth processing station 134 separated by a distance d₂. The distance d₂ can be different than the distance d₁ associated with the first processing chamber.

The robot arms 152 and 154 can be extended independent of one another (e.g., using independent drive mechanisms) to individually place a workpiece on the third processing station 132 and the fourth processing station 134 respectively. For instance, as shown in FIG. 5C, the workpiece handling robot 150 can be configured to first extend the second robot arm 154 to place the workpiece on the fourth processing station 134. The workpiece handling robot 150 can then retract the second robot arm 154. As shown in FIG. 5D, the workpiece handling robot 150 can then be configured to extend the first robot arm 152 to place the workpiece on the third processing station 132. The workpiece handling robot 150 can then retract the first robot arm 152. In alternative embodiments, the workpiece handling robot 150 can be configured to extend the first robot arm 152 and the second robot arm 154 to place workpieces on the third processing station 132 and the fourth processing station 134 at the same time. In this way, the workpiece handling robot can accommodate the transfer of workpieces among dual workpiece chambers having different spacing between processing stations.

The workpieces can be subjected to a process (e.g., a thermal treatment process, anneal process, etch process, strip process, deposition process, surface treatment process) in the second processing chamber 120. The second process can be different than the first process After completion of the second process, the workpiece handling robot 150 can be configured to grab the workpieces from the workpiece processing stations 132 and 134 using independent extension of robot arms 152 and 154 and transfer the workpieces back to the workpiece support column 110 in the load lock chamber 114.

FIGS. 6A to 6F depict example operation of an example workpiece handling robot 150 in a processing platform 200 according to example aspects of the present disclosure. The workpiece handling robot 150 can be similar to the workpiece handling robot 150 shown in FIG. 4 and can be configured to provide for the independent extension and/or retraction of each of a plurality of robot arms.

More particularly, for instance, the workpiece handling robot 150 can include a first robot arm 152 and a second robot arm 154. A first workpiece handling component can be associated with the first robot arm 152. The first workpiece handling component can be a workpiece blade, end effector, etc. configured to pick up, hold, and drop off one or more workpieces. A second workpiece handling component can be associated with the second robot arm 154. The second workpiece handling component can be a workpiece blade, end effector, etc. configured to pick up, hold, and drop off one or more workpieces.

As shown in FIG. 6A, both robot arms 152 and 154 of the rotary robot 150 can be independently extended (e.g., using independent drive mechanisms) to grab a workpiece from the workpiece support column 210 in the load lock chamber 214. For instance, robot arm 152 can be extended to grab a workpiece from workpiece support column 210. Robot arm 154 can be extended to grab a workpiece from workpiece support column 210. In some embodiments, the robot arms 152 and 154 can be extended to grab workpieces from the workpiece support column 110 at the same time. After grabbing the workpieces from the workpiece support column 210, the workpiece handling robot 150 can then be operated to retract the robot arms 152 and 154 to a retracted position.

As shown in FIG. 6B, the workpiece handling robot 150 can be rotated so that the robot arms 152 and 154 face a first processing chamber 220. The first processing chamber can be a dual workpiece processing chamber having a first processing station 222 and a second processing station 224 separated by a distance d₁. The first processing chamber 220 can be operable at a pressure of less than 10 Torr. The robot arms 152 and 154 can be extended independent of one another (e.g., using independent drive mechanisms) to individually place a workpiece on the first processing station 222 and the second processing station 224 respectively. As shown in FIG. 5B, the workpiece handling robot 150 can be configured to extend the robot arms 152 and 154 to place the workpieces on the first processing station 222 and the second procession station 224 at the same time.

The workpieces can be subjected to a process (e.g., a thermal treatment process, anneal process, etch process, strip process, deposition process, surface treatment process) in the first processing chamber 120. After completion of the process, the workpiece handling robot 150 can be configured to grab the workpieces from the workpiece processing stations 222 and 224 using independent extension of robot arms 152 and 154. After grabbing the workpieces, the workpiece handling robot 150 can then be operated to retract the robot arms 152 and 154 (e.g., using independent drive mechanisms) to a retracted position.

As shown in FIGS. 6C and 6D, the workpiece handling robot 150 can be rotated such that the robot arms 152 and 154 face second and third processing chambers 240 and 250. The second processing chamber 240 can be a single workpiece processing chamber having a single processing station 242. The third processing chamber 250 can be a single workpiece processing chamber having a single processing station 252. Each of the second processing chamber 240 and the third processing chamber can be operable at a pressure of less than about 10 Torr.

As shown in FIG. 6C, the workpiece handling robot 150 can extend the second arm 154 to place a workpiece in the second processing chamber 240. The workpiece can be subjected to a process (e.g., a thermal treatment process, anneal process, etch process, strip process, deposition process, surface treatment process) in the second processing chamber 240. After completion of the process, the workpiece handling robot 150 can be configured to grab the workpiece from the workpiece processing station 242 using independent extension of robot arm 154. After grabbing the workpiece, the workpiece handling robot 150 can then be operated to retract the robot arm 154 to a retracted position.

Similarly, as shown in FIG. 6D, the workpiece handling robot 150 can extend the first arm 152 to place a workpiece in the third processing chamber 250. The workpiece can be subjected to a process (e.g., a thermal treatment process, anneal process, etch process, strip process, deposition process, surface treatment process) in the third processing chamber 250. After completion of the process, the workpiece handling robot 150 can be configured to grab the workpiece from the workpiece processing station 252 using independent extension of robot arm 152. After grabbing the workpiece, the workpiece handling robot 150 can then be operated to retract the robot arm 152 to a retracted position.

As shown in FIG. 6F, the workpiece handling robot 150 can be rotated so that the robot arms 152 and 154 face a fourth processing chamber 230. The fourth processing chamber 230 can be operable at a pressure of less than 10 Torr. The fourth processing chamber 230 can be a dual workpiece processing chamber having a third processing station 232 and a fourth processing station 234 separated by a distance d₂. The distance d₂ can be different than the distance d associated with the first processing chamber 220.

The robot arms 152 and 154 can be extended independent of one another (e.g., using independent drive mechanisms) to individually place a workpiece on the third processing station 232 and the fourth processing station 234 respectively. As shown in FIG. 6F, the workpiece handling robot 150 can be configured to extend the robot arms 152 and 154 to place the workpieces on the third processing station 232 and the fourth procession station 234 at the same time.

The workpiece can be subjected to a process (e.g., a thermal treatment process, anneal process, etch process, strip process, deposition process, surface treatment process) in the fourth processing chamber 230. After completion of the process, the workpiece handling robot 150 can be configured to grab the workpieces from the workpiece processing stations 232 and 234 using independent extension of robot arms 152 and 154. After grabbing the workpieces, the workpiece handling robot 150 can then be operated to retract the robot arms 152 and 154 (e.g., using independent drive mechanisms) to a retracted position.

The above examples of operation of a workpiece handling robot for transferring workpieces in a processing system are provided for purposes of illustration and discussion. Those of ordinary skill in the art, using the disclosures provided herein, will understand that many different modes of operating the workpiece handling robot can be used without deviating from the scope of the present disclosure.

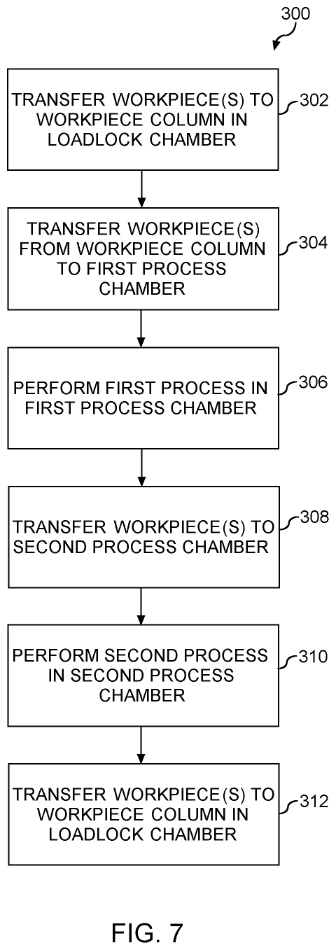

FIG. 7 depicts a flow diagram of an example method (300) for processing a workpiece in a processing system. The method (300) can be implemented using the processing system 100 of FIG. 1. FIG. 7 depicts steps performed in a particular order for purposes of illustration and discussion. Those of ordinary skill in the art, using the disclosures provided herein, will understand that various steps of any of the methods provided herein can be adapted, rearranged, expanded, performed simultaneously, omitted, include steps not illustrated, and/or modified in various ways without deviating from the scope of the present disclosure.

At (302), the method can include transferring a plurality of workpieces to a workpiece support column in a load lock chamber. The workpieces can be positioned in a stacked arrangement (e.g., on a plurality of shelves) in the workpiece support column.

At (304), the method can include transferring, with a workpiece handling robot located in a transfer chamber, the plurality of workpieces from the workpiece support column to at least two processing stations in a first processing chamber. The at least two processing stations can be separated by a distance.

For instance, a workpiece handling robot can use independent extension of arms to grab workpieces from the workpiece support column. The workpiece handling robot can use independent extension of arms to place the workpieces in the two processing stations in the first processing chamber. The two workpieces can be placed in the first processing chamber at the same time or at different times.

At (306), the method includes performing a first process on the plurality of workpieces in the first processing chamber. The first treatment process can include, for instance, an anneal process, a thermal treatment process, a surface treatment process, a dry strip processes, a dry etch process, a deposition process or other process.

At (308), the method includes transferring, with the workpiece handling robot, the plurality of workpieces to at least two processing stations in a second processing chamber. The at least two processing stations can be separated by a distance. The distance between the two processing stations in the second processing chamber can be different from the distance between the two processing stations in the first processing chamber.

For instance, a workpiece handling robot can use independent extension of arms to grab workpieces from the first processing chamber. The workpiece handling robot can rotate about an axis such that the robot arms face the second processing chamber. The workpiece handling robot can use independent extension of arms to place the workpieces in the two processing stations in the second processing chamber. The two workpieces can be placed in the second processing chamber at the same time or at different times.

At (310), the method includes performing a second workpiece process on the plurality of workpieces in the second processing chamber. The second workpiece process can include, for instance, an anneal process, a thermal treatment process, a surface treatment process, a dry strip processes, a dry etch process, a deposition process or other process. In some embodiments, the second workpiece process can be the same as or different from the first workpiece process.

At (312), the method can include transferring the processed workpieces back to the workpiece support column in the load lock chamber. For instance, the workpiece handling robot can use independent extension of arms to grab workpieces from the second processing chamber. The workpiece handling robot can rotate about an axis such that the robot arms face the workpiece support column in the load lock chamber. The workpiece handling robot can use independent extension of arms to place the workpieces in the workpiece support column.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A workpiece processing apparatus for processing semiconductor workpieces, comprising:
a first processing chamber comprising a first processing station and a second processing station, wherein the first processing chamber is operable at a pressure of less than about 10 torr, wherein the first processing station and the second processing station are separated by a first distance;
one or more second processing chambers, the one or more second processing chambers collectively comprising a third processing station and a fourth processing station, wherein the one or more second processing chambers are operable at a pressure of less than about 10 torr, the third processing station and the fourth processing station being separated by a second distance, the second distance being different from the first distance;
a transfer chamber in process flow communication with the first processing chamber and the one or more second processing chambers, wherein the transfer chamber is operable at a pressure of less than about 10 torr;
a workpiece handling robot disposed in the transfer chamber, the workpiece handing robot configured to rotate about an axis, the workpiece handling robot comprising a first arm and a second arm, the first arm comprising at least one workpiece handling component operable to support a first workpiece, the second arm comprising at least one workpiece handling component operable to support a second workpiece,
wherein the workpiece handling robot is configured to pick up the first workpiece and the second workpiece from the first and second processing stations and to drop off the first workpiece and the second workpiece at the third and fourth processing stations.

2. The workpiece processing apparatus of claim 1, wherein the workpiece handling robot is configured to adjust a lateral distance between the first arm and the second arm.

3. The workpiece processing apparatus of claim 1, wherein the first arm is independently extendable relative to the second arm.

4. The workpiece processing apparatus of claim 1, wherein the workpiece handling robot is configured to transfer the first workpiece and the second workpiece from the first and second processing stations in the first processing chamber to the third and fourth processing stations using independent extension of the first arm and the second arm.

5. The workpiece processing apparatus of claim 1, wherein the third processing station and the fourth second processing station are located in the same processing chamber.

6. The workpiece processing apparatus of claim 1, wherein the third processing station and the fourth processing stations are located in separate processing chambers.

7. The workpiece processing apparatus of claim 1, wherein the third and fourth processing chambers each include a single processing station.

8. The workpiece processing apparatus of claim 1, wherein the workpiece processing apparatus comprises a transfer position having a workpiece support column operable to support the first workpiece and the second workpiece in a stacked arrangement.

9. The workpiece processing apparatus of claim 8, wherein the workpiece handling robot is configured to pick up or drop off the first workpiece and the second workpiece at the same time from the workpiece support column.

10. The workpiece processing apparatus claim 1, further comprising a load lock chamber in process flow communication with the transfer chamber, wherein the load lock chamber is operable to be isolated from the transfer chamber

11. The workpiece processing apparatus of claim 10, wherein the load lock chamber is operable in a pressure from about 10 torr to atmospheric pressure.

12. The workpiece processing apparatus of claim 1 wherein the first processing chamber is an etch process chamber, a dry strip process chamber, a deposition process chamber, a thermal process chamber, an ion implantation process chamber, or a surface treatment process chamber.

13. The workpiece processing apparatus of claim 1, wherein the second processing chamber is an etch process chamber, a dry strip process chamber, a deposition process chamber, a thermal process chamber, an ion implantation process chamber, or a surface treatment process chamber.

14. A system for processing a plurality of semiconductor workpieces, comprising:
a first processing chamber comprising a first processing station and a second processing station, the first processing chamber operable at a pressure of less than about 10 torr, wherein the first processing station and the second processing station separated by a first distance;
a second processing chamber comprising a third processing station, the second processing chamber operable at a pressure of less than about 10 torr;
a third processing chamber comprising a fourth processing station, the third processing chamber operable at a pressure of less than about 10 torr; the third processing station and the fourth processing station being separated by a second distance, the second distance being different from the first distance;
a transfer chamber in process flow communication with the first processing chamber and the one or more second processing chambers, the transfer chamber operable at a pressure of less than about 10 torr;
a workpiece handling robot disposed in the transfer chamber, the workpiece handing robot configured to rotate about an axis, the workpiece handling robot comprising a first arm and a second arm, the first arm comprising at least one workpiece support operable to pick up a first workpiece, the second arm comprising at least one workpiece support operable to pick up a second workpiece, the first arm being independently extendable relative to the second arm;
wherein the workpiece handling robot is configured to transfer the first workpiece and the second workpiece from the first and second processing stations in the first processing chamber to the third and fourth processing stations using independent extension of the first arm and the second arm.

15. The system of claim 14, wherein the system comprises a transfer position having a workpiece support column operable to support the first workpiece and the second workpiece in a stacked arrangement.

16. The system of claim 15, wherein the workpiece handling robot is configured to pick up or drop off the first workpiece and the second workpiece at the same time from the workpiece support column.

17. The system of claim 14, further comprising a load lock chamber in process flow communication with the transfer chamber, wherein the load lock chamber has a workpiece support column and is operable to be isolated from the transfer chamber, wherein the load lock chamber is operable at a pressure from about 10 torr to atmospheric pressure.

18. The system of claim 14, wherein the first processing chamber is an etch process chamber, a dry strip process chamber, a deposition process chamber, a thermal process chamber, an ion implantation process chamber, or a surface treatment process chamber.

19. The system of claim 14, wherein the second processing chamber is an etch process chamber, a dry strip process chamber, a deposition process chamber, a thermal process chamber, an ion implantation process chamber, or a surface treatment process chamber.

20. The system of claim 14, wherein the third processing chamber is an etch process chamber, a dry strip process chamber, a deposition process chamber, a thermal process chamber, an ion implantation process chamber, or a surface treatment process chamber.
